(19) United States
(12) Patent Application Publication
(10) Pub. No.: US 2011/0209983 A1
(43) Pub. Date: Sep. 1, 2011

(54) USE OF HIGH ENERGY HEAVY ION BEAM FOR DIRECT SPUTTERING

(76) Inventors: Gary A. Glass, Lafayette, LA (US); Alexander D. Dymnikov, Lafayette, LA (US); Bibhudutta Rout, Denton, TX (US)

(21) Appl. No.: 12/806,217

(22) Filed: Apr. 3, 2009

(51) Int. Cl. C23C 14/46

(52) U.S. Cl. 204/192.11

(57) ABSTRACT

High energy heavy ions are used to produce free space regions by sputtering the high energy beam through a mask onto a substrate. The invention also includes a method of focusing the high energy beam with a beam focusing system. The invention is in part based on an experiment in which 900 keV gold ions were used to sputter aluminum, copper, silicon and silver. The results demonstrate the possibility that high energy heavy ions could be used to fabricate microstructures in selected metals and silicon in a single step process.

### STATEMENT REGARDING FEDERALLY SPONSORED RESEARCH OR DEVELOPMENT

This invention was supported in part by the National Science Foundation, Grant No. IR21NS42736-01.

### CROSS REFERENCE TO RELATED APPLICATIONS

Not Applicable.

### REFERENCE TO A “SEQUENCE LISTING,” A TABLE, OR A COMPUTER PROGRAM

Not Applicable.

### BACKGROUND OF THE INVENTION

### Field of the Invention

The present invention relates to the use of High Energy Beams (HEHIBs). More particularly, the invention relates to the use of HEHIB s for direct sputtering of a substrate or in metals.

### SUMMARY OF THE INVENTION

The invention uses high energy heavy ions for direct sputtering in a substrate. The inventors have demonstrated the use of Au ions (900 keV) for direct sputter etching of microstructures in silicon, aluminum, copper and silver. The results clearly demonstrate that high energy heavy ions can be used to fabricate microstructures in selected metals, insulators, and silicon in a single step process.

The present invention has several advantages over the prior art systems. One advantage of the present invention is that it can be used to create a wide variety of structures.

These and other objects, advantages, and features of this invention will be apparent from the following description.

### BRIEF DESCRIPTION OF THE DRAWINGS

FIG. 1 is a photograph of grid structures on (a) Si(100), (b) Ag, (c) Cu and (d) Al using a 900 keV Au ion beam.

### DETAILED DESCRIPTION OF THE INVENTION

Bulk micromachining of silicon with precise three-dimensional microscale features remains an actively sought-after area for fabrication of devices with a wide range of applications in photonic crystals, microelectromechanical systems (MEMS), as well as many other applications. This has become possible with extensive uses of chemical (wet) anisotropic etching of silicon via etch-masks made with layers of silicon dioxide (SiO2), silicon nitride (Si₃N₄) or doping of boron. The hydroxides of alkali metals (e.g. KOH, NaOH, CsOH, RbOH, etc.) can be used as crystal orientation dependent etchants of silicon, providing an extra versatility for the production of different structures. The combination of electrochemical etching techniques and high energy ion irradiation is a powerful tool for producing high aspect ratio microstructures. The combination has the potential to be applied in several areas, such as photonics. Moreover, energetic (keV-MeV) Au and Xe irradiation in Si(100), Si(110), n-type via masked, patterned resists (SU(8)) have also been used to create layers in Si(100) resistant to KOH etching.

The direct, maskless, etchless machining of microstructures in silicon, insulators and metals could be even more useful. Although at the present time there are no focusing systems capable of producing heavy ion microbeams with MeV energies for direct write applications, the demonstration of sputter etching of metals described herein is an important step for the development of a high energy focused ion beam (HEFIB) system utilizing heavy ions. This technique relies on the same physical process used in focused ion beam (FIB) applications using specialized ion sources but, in contrast, 900 keV gold ions are used in this study. In direct sputtering, the material is actually removed and free space is create, doing more than merely creating a high resist region.

TABLE 1
Comparison of sputtering** yields for 30 keV Ga and 900 keV Au ions

| | 30 keV Ga | 900 keV Au |
|---|---|---|
| Range in Si (nm) | 27 | 140 |
| Sputter yield in Si (atoms/ion) | 2.6 | 6.3 |
| Range in Al (nm) | 24 | 194 |
| Sputter yield in Al (atoms/ion) | 4.4 | 6.4 |
| Range in Cu (nm) | 10 | 84 |
| Sputter yield in Cu (atoms/ion) | 11 | 14 |
| Range in Ag (nm) | 11 | 82 |
| Sputter yield in Ag (atoms/ion) | 14 | 17 |

**The sputtering yields were calculated using SRIM code [10] with 100 ions incident at 0 to a 10 nm thick target.

As shown in Table 1 the sputter yields for these gold ions were actually greater than the yields for the low energy Ga ions usually used in focused ion beam (FIB). A number of applications have been developed for FIB in commercial instruments. Ga is by far the most widely used ion, but due to the relatively low energy (approximately 30 keV) Ga ions have a very shallow depth of penetration, ≦30 nm in Si, with a radial and lateral straggling of 9 and 14 nm, respectively. The sputtering yields when using high energy Au ions on the substrate materials here are approximately 20-270% larger than the yields obtained using low energy Ga ions, depending on the angle of incidence. These higher sputtering yields indicate the possibility of applying HEFIB techniques for direct nanoscale machining. The resulting structures could be created with higher aspect-ratios due to the much larger penetration depth and significantly smaller scattering of the high energy ions.

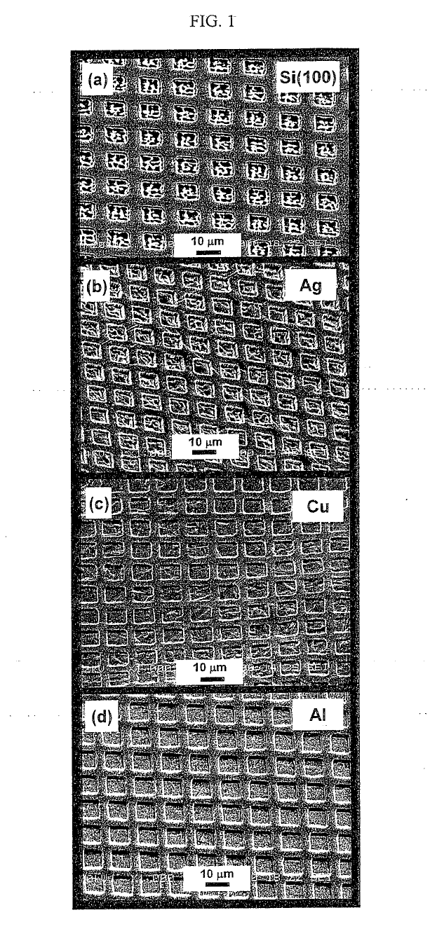

FIG. 1 shows direct etching in Si(100), Ag, Cu and Al with 900 keV Au ions using 2000 mesh Cu SEM calibration grids as masks and utilizing typical gold ion fluences of 1-2×10¹⁷ ions/cm² at normal incidence to the substrates to etch the identical patterns to depths of 1-2 μm. All of the substrates were commercially obtained. The goal of this experiment was to demonstrate the etching process. Therefore no special preparation of the substrates, other than surface cleaning with alcohol, was performed.

The above experiment clearly demonstrates that high energy gold ions can be used for direct etching of silicon, aluminum, copper and silver. The results also indicate the potential application of the direct sputtering techniques to nanoscale fabrication with heavy ions. One particular application for consideration is the use of heavy ion sputtering for maskless, direct write processes. However, such processes would require focusing systems not yet perfected and would also required specialized ion sources that can produce micro/nanobeams of high energy heavy ions. Additionally, it should be noted that the heavy ion sputtering process does have certain drawbacks when compared to other ion techniques. One drawback is that when masks are used, the mask itself is exposed to the ion beam and therefore mask erosion must be addressed prior to the irradiation procedure.

There are focusing systems used with high energy proton beams (p-beams) that control the high energy beams in two dimensions. One focusing system used for focusing high energy beams is as described in U.S. Pat. No. 7,002,160, and Applicants hereby expressly incorporate by reference U.S. Pat. No. 7,002,160 in its entirety. Such focusing systems could be modified and enhanced to focus the High Energy Focused Ion Beam of the present invention, thereby eliminating the need for a mask. Generally, it is easier to focus heavy ions with an electric field instead of the magnetic field used for proton beams.

There are of course other alternate embodiments which are obvious from the foregoing descriptions of the invention, which are intended to be included within the scope of the invention, as defined by the following claims.

1. A method of creating micro structures in a substrate, comprising:
(a) providing a high energy beam focusing system
(b) providing a substrate;
(c) providing a high energy heavy ion beam; and
(d) focusing said beam with said focusing system to sputter selected regions of said substrate and thereby create free space regions.

2. A method of creating micro structures in a substrate, comprising:
(a) providing a substrate;
(b) providing a high energy heavy ion beam;
(c) providing a mask interposed between said substrate and said beam; and
(d) irradiating said substrate with said beam through said mask;
(e) wherein said beam sputters regions in said substrate, thereby creating free space regions corresponding to said mask.

3. The method in claim 1, wherein said focusing system uses an electric field to focus the high energy beam.

4. The method in claim 1, wherein said focusing system is a quadrupole lens system comprising six quadrupole lenses in a linear configuration comprised of two triplets, such that: i) the focusing (F) and defocusing (D) capabilities of the lenses in one plane alternate F-D-F-D-F-D; and ii) the lenses are ordered A-B-C-C-B-A; and iii) the lengths of the lenses (1.sub.j) and the distances between lenses (s.sub.k) are ordered as 1.sub.1-s.sub.1-1.sub.2-s.sub.2-1.sub.3-s.sub.3-1.sub.3-s.sub.2-1.sub.2-s-.sub.1-1.sub.1; and iv) every two identical lenses are rotated 90 degrees from each other.
